(19) United States
(12) Patent Application Publication
(10) Pub. No.: US 2025/0283951 A1
(43) Pub. Date: Sep. 11, 2025

(54) BATTERY DIAGNOSTIC CHARGING PROTOCOL

(71) Applicant: Toyota Research Institute, Inc., Los Altos, CA (US)

(72) Inventors: Steven Torrisi, Berkeley, CA (US); Amalie Trewartha, San Francisco, CA (US)

(73) Assignees: Toyota Research Institute, Inc., Los Altos, CA (US); Toyota Jidosha Kabushiki Kaisha, Toyota-shi Aichi-ken (JP)

(21) Appl. No.: 18/600,969

(22) Filed: Mar. 11, 2024

(51) Int. Cl. G01R 31/392; G01R 31/36; G01R 31/367; H02J 7/00

(52) U.S. Cl. CPC G01R 31/392; G01R 31/3646; G01R 31/367; H02J 7/005; H02J 7/00712

(57) ABSTRACT

Systems and methods described herein relate to implementing measuring battery performance during charging. In one embodiment, a method includes receiving a diagnostic charging protocol and a set of testing points, restoring energy to a battery when the battery is determined not to be within the set of testing points, ceasing restoring energy and testing the battery when the battery is determined to be within the set of testing points, and determining battery model parameters based on battery measurements at a subset of testing points.

### TECHNICAL FIELD

The subject matter described herein relates, in general, to strategies for diagnosing battery performance during charging.

### BACKGROUND

The value of an electric vehicle is often determined by the health of its electric vehicle battery. Typically, the health of a vehicle battery is determined by analyzing the performance of the battery during a discharge cycle. For example, measurements of voltage and current during discharge may be used to evaluate the health of the battery.

### SUMMARY

In one embodiment, a compensation measure system is disclosed. The vehicle management system includes one or more processors and a memory communicably coupled to the one or more processors. The memory stores a command module including instructions that when executed by the one or more processors cause the one or more processors to receive a diagnostic charging protocol and a set of testing points, restore energy to a battery when the battery is determined not to be within the set of testing points, cease restoring energy and apply a test to the battery when the battery is determined to be within the set of testing points, and determine battery model parameters based on battery measurements at a subset of testing points.

In one embodiment, a non-transitory computer-readable medium including instructions that when executed by one or more processors cause the one or more processors to perform one or more functions is disclosed. The instructions include instructions to receive a diagnostic charging protocol and a set of testing points, restore energy to a battery when the battery is determined not to be within the set of testing points, cease restoring energy and apply a test to the battery when the battery is determined to be within the set of testing points, and determine battery model parameters based on battery measurements at a subset of testing points.

In one embodiment, a method is disclosed. In one embodiment, the method includes receiving a diagnostic charging protocol and a set of testing points, restoring energy to a battery when the battery is determined not to be within the set of testing points, ceasing restoring energy and apply a test to the battery when the battery is determined to be within the set of testing points, and determining battery model parameters based on battery measurements at a subset of testing points.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates one embodiment of a vehicle within which systems and methods disclosed herein may be implemented.

FIG. 2 illustrates one embodiment of a battery diagnostic system that is associated with diagnosing battery performance.

FIG. 3 illustrates one embodiment of a cloud computing environment within which the systems and methods described herein may operate.

FIG. 4 illustrates one example of an RC equivalent battery model.

FIG. 5 illustrates one example of an HPPC test.

FIG. 6 illustrates one example of a traditional charging cycle.

FIG. 7 illustrates one example of a charging cycle using a battery diagnostic charging protocol.

FIG. 8 illustrates one example of a method for diagnosing battery performance.

### DETAILED DESCRIPTION

Systems, methods, and other embodiments associated with measuring battery performance are described herein. With respect to estimating the battery performance of an electric vehicle, traditional methods focus on the performance of the battery during discharge. For example, measurements of battery voltage and current may be used to determine an estimate of battery health. In addition, charging of electric vehicle batteries is often a rather straightforward process, typically involving a charger using constant current charging to a desired voltage, after which constant potential charging is used.

An improvement to these traditional approaches is the use of a battery diagnostic charging protocol as described herein, which may be used with a battery diagnostic system. With a battery diagnostic charging protocol, both charging and diagnostic testing to determine an estimate of battery performance may be performed during the charge cycle. In such an approach, pauses in charging may be undertaken at selected testing points to perform battery tests, after which charging may resume.

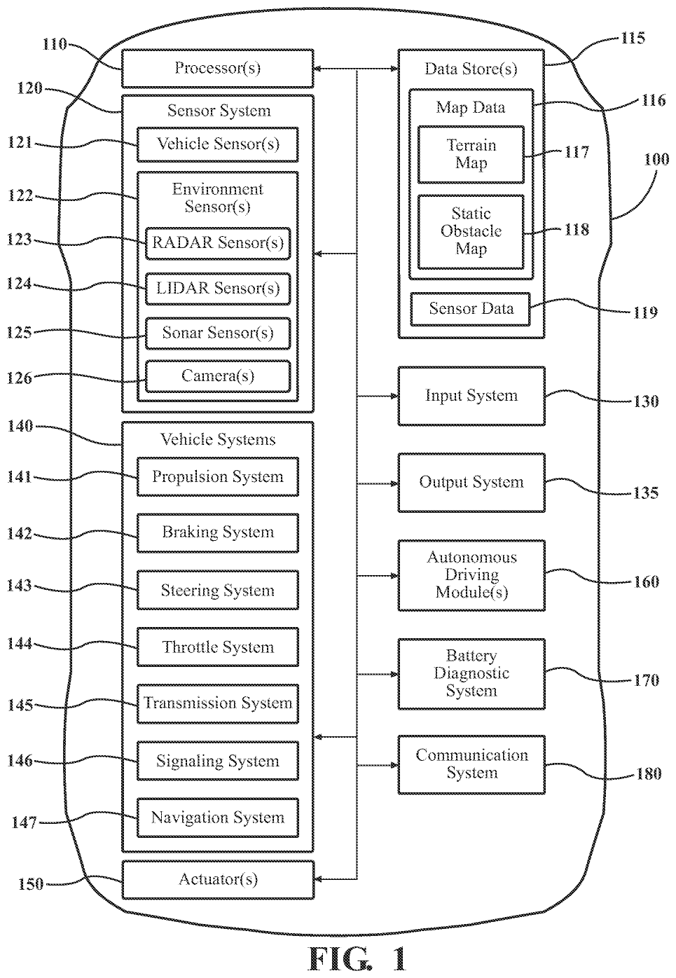

Referring to FIG. 1, an example of a vehicle 100 is illustrated. As used herein, a “vehicle” is any form of motorized transport. In one or more implementations, vehicle 100 is an automobile. While arrangements will be described herein with respect to automobiles, it will be understood that embodiments are not limited to automobiles. In some implementations, vehicle 100 may be any robotic device or form of motorized transport that, for example, includes sensors to perceive aspects of the surrounding environment, and thus benefits from the functionality discussed herein associated with diagnostic charging strategies. As a further note, this disclosure generally discusses vehicle 100 as traveling on a roadway with surrounding vehicles, which are intended to be construed in a similar manner as vehicle 100 itself. That is, the surrounding vehicles may include any vehicle that may be encountered on a roadway by vehicle 100.

Vehicle 100 also includes various elements. It will be understood that in various embodiments it may not be necessary for vehicle 100 to have all of the elements shown in FIG. 1. Vehicle 100 may have any combination of the various elements shown in FIG. 1. Further, vehicle 100 may have additional elements to those shown in FIG. 1. In some arrangements, vehicle 100 may be implemented without one or more of the elements shown in FIG. 1. While the various elements are shown as being located within vehicle 100 in FIG. 1, it will be understood that one or more of these elements may be located external to vehicle 100. Further, the elements shown may be physically separated by large distances. For example, as discussed, one or more components of the disclosed system may be implemented within a vehicle while further (01116479) 3 components of the system are implemented within a cloud-computing environment or other system that is remote from vehicle 100.

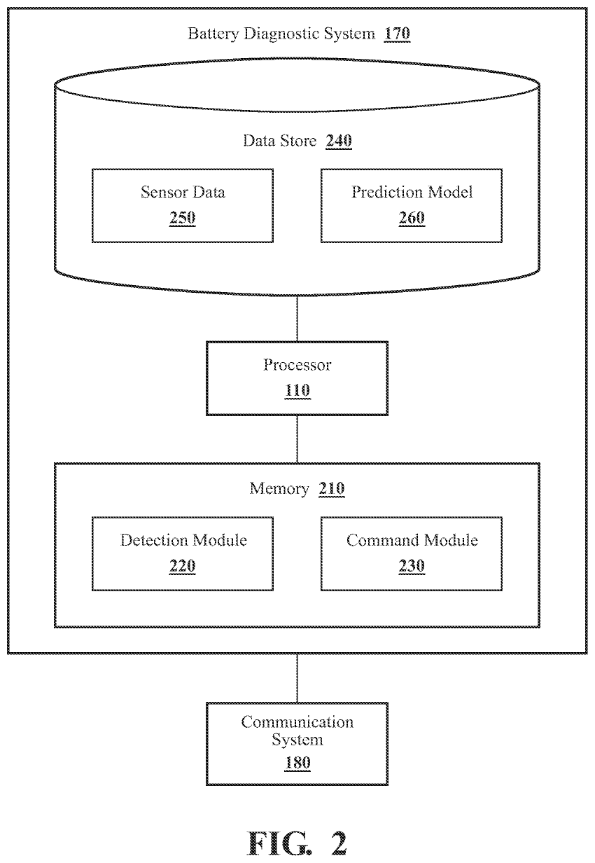

Some of the possible elements of vehicle 100 are shown in FIG. 1 and will be described along with subsequent figures. However, a description of many of the elements in FIG. 1 will be provided after the discussion of FIGS. 2-8 for purposes of brevity of this description. Additionally, it will be appreciated that for simplicity and clarity of illustration, where appropriate, reference numerals have been repeated among the different figures to indicate corresponding or analogous elements. In addition, the discussion outlines numerous specific details to provide a thorough understanding of the embodiments described herein. Those of skill in the art, however, will understand that the embodiments described herein may be practiced using various combinations of these elements. In either case, vehicle 100 includes a battery diagnostic system 170 that is implemented to perform methods and other functions as disclosed herein relating to implementing vehicle seat force tracking. As will be discussed in greater detail subsequently, battery diagnostic system 170, in various embodiments, is implemented partially within vehicle 100 and as a cloud-based service. For example, in one approach, functionality associated with at least one module of battery diagnostic system 170 is implemented within vehicle 100 while further functionality is implemented within a cloud-based computing system.

With reference to FIG. 2, one embodiment of battery diagnostic system 170 of FIG. 1 is further illustrated. Battery diagnostic system 170 is shown as including processor(s) 110 from vehicle 100 of FIG. 1. Accordingly, processor(s) 110 may be a part of battery diagnostic system 170, battery diagnostic system 170 may include a separate processor from processor 110 (s) of vehicle 100, or battery diagnostic system 170 may access processor 110 (s) through a data bus or another communication path. In one embodiment, battery diagnostic system 170 includes memory 210, which stores detection module 220 and command module 230. Memory 210 is a random-access memory (RAM), read-only memory (ROM), a hard-disk drive, a flash memory, or other suitable memory for storing detection module 220 and command module 230. Detection module 220 and command module 230 are, for example, computer-readable instructions that when executed by processor(s) 110 cause processor(s) 110 to perform the various functions disclosed herein.

Battery diagnostic system 170 as illustrated in FIG. 2 is generally an abstracted form of battery diagnostic system 170 as may be implemented between vehicle 100 and a cloud-computing environment. Accordingly, battery diagnostic system 170 may be embodied at least in part within a cloud-computing environment to perform the methods described herein.

With reference to FIG. 2, detection module 220 generally includes instructions that function to control processor(s) 110 to receive data inputs from one or more sensors of vehicle 100. The inputs are, in one embodiment, observations of one or more objects in an environment proximate to vehicle 100, other aspects about the surroundings, or both. As provided for herein, detection module 220, in one embodiment, acquires sensor data 250 that includes at least camera images. In further arrangements, detection module 220 acquires sensor data 250 from further sensors such as radar 123, LiDAR 124, and other sensors as may be suitable for identifying vehicles, locations of the vehicles, lane markers, crosswalks, traffic signs, vehicle parking areas, road surface types, curbs, vehicle barriers, and so on. In one embodiment, detection module 220 may also acquire sensor data 250 from one or more sensors that allow for implementing vehicle seat force tracking.

Accordingly, detection module 220, in one embodiment, controls the respective sensors to provide sensor data 250. Additionally, while detection module 220 is discussed as controlling the various sensors to provide sensor data 250, in one or more embodiments, detection module 220 may employ other techniques to acquire sensor data 250 that are either active or passive. For example, detection module 220 may passively sniff sensor data 250 from a stream of electronic information provided by the various sensors to further components within vehicle 100. Moreover, detection module 220 may undertake various approaches to fuse data from multiple sensors when providing sensor data 250, from sensor data acquired over a wireless communication link (e.g., v2v) from one or more of the surrounding vehicles, or from a combination thereof. Thus, sensor data 250, in one embodiment, represents a combination of perceptions acquired from multiple sensors.

In addition to locations of surrounding vehicles, sensor data 250 may also include, for example, odometry information, GPS data, or other location data. Moreover, detection module 220, in one embodiment, controls the sensors to acquire sensor data about an area that encompasses 360 degrees about vehicle 100, which may then be stored in sensor data 250. In some embodiments, such area sensor data may be used to provide a comprehensive assessment of the surrounding environment around vehicle 100. Of course, in alternative embodiments, detection module 220 may acquire the sensor data about a forward direction alone when, for example, vehicle 100 is not equipped with further sensors to include additional regions about the vehicle or the additional regions are not scanned due to other reasons (e.g., unnecessary due to known current conditions).

Moreover, in one embodiment, battery diagnostic system 170 includes a database 240. Database 240 is, in one embodiment, an electronic data structure stored in memory 210 or another data store and that is configured with routines that may be executed by processor(s) 110 for analyzing stored data, providing stored data, organizing stored data, and so on. Thus, in one embodiment, database 240 stores data used by the detection module 220 and command module 230 in executing various functions. In one embodiment, database 240 includes sensor data 250 along with, for example, metadata that characterize various aspects of sensor data 250. For example, the metadata may include location coordinates (e.g., longitude and latitude), relative map coordinates or tile identifiers, time/date stamps from when separate sensor data 250 was generated, and so on.

Detection module 220, in one embodiment, is further configured to perform additional tasks beyond controlling the respective sensors to acquire and provide sensor data 250. For example, detection module 220 includes instructions that may cause processor(s) 110 to obtain battery measurements as described herein. In some embodiments, detection module 220 may receive and store battery measurements.

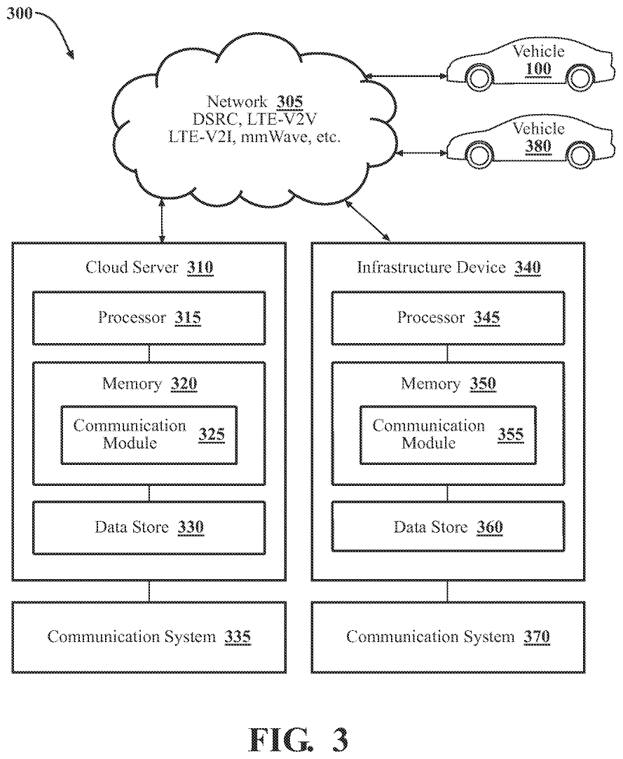

In one embodiment, command module 230 generally includes instructions that function to control the processor(s) 110 or collection of processors in the cloud-computing environment 300 as shown in FIG. 3.

With reference to FIG. 3, vehicle 100 may be connected to a network 305, which allows for communication between vehicle 100 and cloud servers (e.g., cloud server 310), infrastructure devices (e.g., infrastructure device 340), other vehicles (e.g., vehicle 380), and any other systems connected to network 305. With respect to network 305, such a network may use any form of communication or networking to exchange data, including but not limited to the Internet, Directed Short Range Communication (DSRC) service, LTE, 5G, millimeter wave (mmWave) communications, and so on.

Cloud server 310 is shown as including a processor 315 that may be a part of battery diagnostic system 170 through network 305 via communication unit 335. In one embodiment, cloud server 310 includes a memory 320 that stores a communication module 325. Memory 320 is a random-access memory (RAM), read-only memory (ROM), a hard-disk drive, a flash memory, or other suitable memory for storing communication module 325. Communication module 325 is, for example, computer-readable instructions that when executed by processor 315 causes processor 315 to perform the various functions disclosed herein. Moreover, in one embodiment, cloud server 310 includes database 330. Database 330 is, in one embodiment, an electronic data structure stored in a memory 320 or another data store and that is configured with routines that may be executed by processor 315 for analyzing stored data, providing stored data, organizing stored data, and so on.

Infrastructure device 340 is shown as including a processor 345 that may be a part of battery diagnostic system 170 through network 305 via communication unit 370. In one embodiment, infrastructure device 340 includes a memory 350 that stores a communication module 355. Memory 350 is a random-access memory (RAM), read-only memory (ROM), a hard-disk drive, a flash memory, or other suitable memory for storing communication module 355. Communication module 355 is, for example, computer-readable instructions that when executed by processor 345 causes processor 345 to perform the various functions disclosed herein. Moreover, in one embodiment, infrastructure device 340 includes a database 360. Database 360 is, in one embodiment, an electronic data structure stored in memory 350 or another data store and that is configured with routines that may be executed by processor 345 for analyzing stored data, providing stored data, organizing stored data, and so on.

Accordingly, in addition to information obtained from sensor data 250, battery diagnostic system 170 may obtain information from cloud servers (e.g., cloud server 310), infrastructure devices (e.g., infrastructure device 340), other vehicles (e.g., vehicle 380), and any other systems connected to network 305. For example, cloud servers (e.g., cloud server 310) may be used to perform the same tasks as described herein with respect to command module 230. For example, infrastructure device 340 may detect within its coverage area the number of vehicles awaiting charging, such that infrastructure device 340 may determine that it should not allow charging vehicles to perform the diagnostic charging protocol if the number of vehicles is above a pre-determined threshold.

The performance of a rechargeable battery, such as a lithium-ion or sodium-ion battery, is typically governed by its internal resistance, which may change with respect to temperature, state of charge, state of health, or other factors. Given this variation in internal resistance, a battery charger typically takes either a constant current or constant potential approach to charging rechargeable batteries. With respect to the constant current mode, a constant current may be used to charge the rechargeable battery, such that the changes in the internal resistance of the battery cause the charging voltage to vary. With respect to the constant potential mode, a constant voltage may be used to charge the rechargeable battery, such that the changes in the internal resistance of the battery cause the charging current to vary. Accordingly, depending on which mode is used, at least one parameter will vary in accordance with the changing internal resistance of the battery. The measurement of such a varying parameter may then allow for estimating the internal resistance of a battery according to an equivalent circuit model.

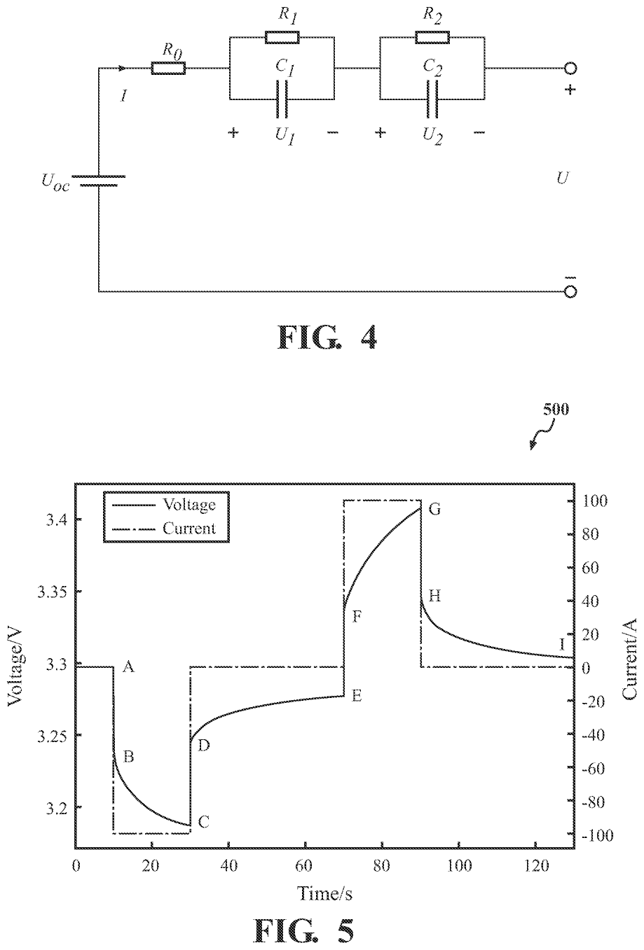

With respect to FIG. 4, an example of an RC equivalent circuit model for a rechargeable battery is shown. In such a second-order RC equivalent circuit model, which consists of a voltage source, a resistor, and two RC networks in series: U_{oc} may denote the battery open-circuit voltage, R₀ may denote the battery ohmic resistance, R₁ and R₂ may respectively denote the charge transfer resistor and polarization resistor, and C₁ and C₂ may respectively denote the charge transfer capacitor and polarization capacitor. Furthermore, τ₁ may denote the time constant for the first RC network where τ₁=R₁C₁ and τ₂ may denote the time constant for the second RC link where τ2=R₂C₂. Finally, I may denote the battery current, U may denote the battery voltage, U₁ and U₂ may respectively denote the terminal voltages of the two RC networks.

According to Kirchhoff's law, a basic relationship between the above variables may be given as follows:

$$U ( t ) = {U}_{OC} - {IR}_{0} - {U}_{1} - {U}_{2} , \qquad Equation ( 1 )$$

$$I = \frac{{U}_{1}}{{R}_{1}} + {C}_{1} \frac{{dU}_{1}}{dt} = \frac{{U}_{2}}{{R}_{2}} + {C}_{2} \frac{{dU}_{2}}{dt} . \qquad Equation ( 2 )$$

With respect to FIG. 5, an example of a voltage and current curves for a rechargeable battery under a hybrid pulse power characterization (“HPPC”) test is shown. In view of the values at positions A through H of the voltage curve, the ohmic resistance R₀ may be obtained as follows:

$${R}_{0 , discharge} = \frac{( {U}_{A} - {U}_{B} ) + ( {U}_{D} - {U}_{C} )}{2 I} , \qquad Equation ( 3 )$$

$${R}_{0 , charge} = \frac{( {U}_{F} - {U}_{E} ) + ( {U}_{G} - {U}_{H} )}{2 I} , \qquad Equation ( 4 )$$

$${R}_{0 , average} = \frac{{R}_{0 , discharge} + {R}_{0 , charge}}{2} , \qquad Equation ( 5 )$$

where Uₙ denotes the voltage measurement at position n=A, . . . , H and I denotes the battery current.

Based on Equation (1) and Equation (2), the following may be obtained:

$$U ( t ) = {U}_{OC} - {IR}_{0} - {U}_{1} ( t ) - {U}_{2} ( t ) , \qquad Equation ( 6 )$$

$${U}_{1} ( t ) = {U}_{1} ( 0 ) {e}^{- \frac{t}{{τ}_{1}}} + {IR}_{1} ( 1 - {e}^{- \frac{t}{{τ}_{1}}} ) , \qquad Equation ( 7 )$$

$${U}_{2} ( t ) = {U}_{2} ( 0 ) {e}^{- \frac{t}{{τ}_{2}}} + {IR}_{2} ( 1 - {e}^{- \frac{t}{{τ}_{2}}} ) , \qquad Equation ( 8 )$$

where U₁(0) and U₂(0) are the initial voltages at both ends of the polarization capacitor in each stage.

Segment BC is the zero-state response of RC networks to the change in input current and the voltages at both ends of the polarization capacitors may be obtained as follows:

$${U}_{1} ( t ) = {IR}_{1} ( 1 - {e}^{- \frac{t}{{τ}_{2}}} ) , \qquad Equation ( 9 )$$

$${U}_{2} ( t ) = {IR}_{2} ( 1 - {e}^{- \frac{t}{{τ}_{2}}} ) , \qquad Equation ( 10 )$$

For the segment CD the polarization voltage can be seen as remaining unchanged until after point D of the voltage curve, such that the initial voltage at both ends of the polarization capacitors may be obtained as follows:

$${U}_{1} ( 0 ) = {IR}_{1} ( 1 - {e}^{- \frac{T}{{τ}_{1}}} ) , \qquad Equation ( 11 )$$

$${U}_{2} ( 0 ) = {IR}_{2} ( 1 - {e}^{- \frac{T}{{τ}_{2}}} ) , \qquad Equation ( 12 )$$

where T is the pulse duration of segment BC (e.g., 20 s).

For the segment DE the input current is 0, which can be used as a zero-input response to obtain the battery voltage as follows:

$$U ( t ) = {U}_{OC} - {U}_{1} ( 0 ) {e}^{- \frac{t}{{τ}_{1}}} - {U}_{2} ( 0 ) {e}^{- \frac{t}{{τ}_{2}}} , \qquad Equation ( 13 )$$

Accordingly, the values of U₁(0), U₂(0), τ₁, and τ₂ may be obtained by fitting a curve of Equation (13) to voltage measurements over the segment DE. Once a fit is obtained, values of R₁, R₂, C₁, and C₂ for the discharge cycle may be obtained as follows:

$${R}_{1} = \frac{{U}_{1} ( 0 )}{I ( 1 - {e}^{- \frac{T}{{τ}_{1}}} )} , \qquad Equation ( 14 )$$

$${R}_{2} = \frac{{U}_{2} ( 0 )}{I ( 1 - {e}^{- \frac{T}{{τ}_{2}}} )} , \qquad Equation ( 15 )$$

$${C}_{1} = \frac{{τ}_{1}}{{R}_{1}} , \qquad Equation ( 16 )$$

$${C}_{2} = \frac{{τ}_{2}}{{R}_{2}} . \qquad Equation ( 17 )$$

The process described above may be repeated with respect to segment HI to obtain R₁, R₂, C₁, and C₂ for the charge cycle. Average values may then be obtained for R₁, R₂, C₁, and C₂ based on the values obtained with respect to both the charge cycle and discharge cycle.

It should be noted that while the above is one example of using an RC equivalent model, other battery models may be also used such as higher-order RC equivalent models. In addition, it should be noted that while the above is also one example of using an HPPC test to obtain the parameters of an RC equivalent model, other methods for obtaining battery parameters may also be used.

In some embodiments, command module 230 may receive a diagnostic charging protocol. For example, a diagnostic charging protocol may instruct vehicle 100 when to cease charging and then apply a test to obtain parameters for a battery model, such as an RC equivalent model, at multiple testing points. For instance, a vehicle may be instructed to pause charging every ten minutes, when the estimated state of charge increases by 10%, or other metrics such as length of time (e.g., every 30 minutes). During each pause, command module 230 may be instructed to use a battery test, such as an HPPC test to obtain model parameters. For example, each pause may be initiated with a period of rest to achieve battery equilibration, followed by a discharge pulse at a high current for a short period, followed by a relaxation period, followed by a charge pulse at high current for a short period, and then followed by another relaxation period, after which charging may resume. In some embodiments, such a battery test may be repeated, such as by using different timing between pulses or different levels of discharge/charge pulses within the battery test (e.g., subsequent discharge/charge pulses may increase or decrease in terms of magnitude, frequency, or both). In some embodiments, the length of the relaxation periods and charging/discharging periods may also be varied according to the time it requires the battery to reach equilibration. As part of the diagnostic charging protocol, command module 230 may record the battery voltage, battery current, and other battery parameters during battery tests.

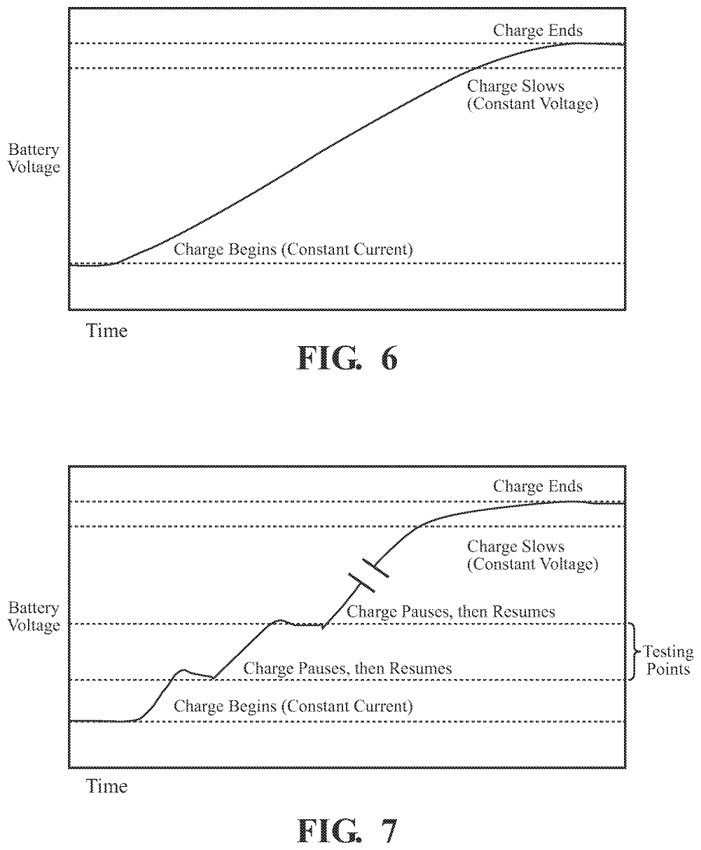

With respect to FIG. 6, an example of a traditional charging cycle is shown, where the charger begins and stays in a constant current charging until it reaches a threshold where the charger switches to constant voltage charging. With respect to FIG. 7, an example of a charging cycle using a diagnostic charging protocol is shown, where pauses are taken at testing points to implement battery tests. It should be understood that while FIG. 7 only shows a battery test involving a rest period to achieve battery equilibrium, other battery tests may be implemented at testing points such as an HPPC test or others.

In some embodiments, command module 230 may be prompted to start charging vehicle 100 according to a diagnostic charging protocol. For example, a battery may be substantially depleted and automatically employ the diagnostic charging protocol during vehicle charging. As another example, command module 230 may receive an instruction to employ the diagnostic charging protocol during vehicle charging. In some embodiments, a vehicle operator must approve or initiate the use of the diagnostic charging protocol before it is implemented during vehicle charging. For example, the vehicle operator may be informed that the diagnostic charging protocol will add 10 minutes in charging to a desired target, such as 80% capacity, which may be rejected by the vehicle operator (e.g., because they are in a hurry). In some embodiments, a vehicle may be instructed that it cannot implement the diagnostic charging protocol, such as because a vehicle charging system does not support the diagnostic charging protocol, is a public charger, or other limitations (e.g., day/time restrictions, number of vehicles waiting to charge exceeds threshold).

In some embodiments, command module 230 may receive battery measurements, such as battery voltage, battery current, battery temperature, etc., that were obtained during a battery test. Based on the battery measurements, command module 230 may apply curve fitting, machine learning, or other techniques to determine the parameters of a battery model, such as an RC equivalent model, that matches the battery measurements. In some embodiments, command module 230 may require that the parameters of the battery model achieve a match with the battery measurements within one or more conditions (e.g., better than 99% match; standard deviation of error below a certain threshold). If command module 230 finds that a satisfactory match cannot be obtained, command module 230 may determine that the battery model is invalid.

In some embodiments, command module 230 may perform analysis with respect to one or more battery models at one or more testing points. For example, at each testing point at a different state of charge (e.g., 10%, 20%, 30%), command module 230 may have a set of model parameters associated with each state of charge, which command module may then use to determine estimates of battery characteristics, such as anode or cathode degradation, state of health, fast charging capability, or other metrics.

For example, command module 230 may use resistance values of one or more battery models at low states of charge (e.g., under 25%) to determine an estimate of anode degradation of a battery. Similarly, command module 230 may use resistance values of one or more battery models at a high states of charge (e.g., over 75%) to determine an estimate of cathode degradation of a battery. In such an embodiment, command module 230 may receive a prediction model 260 trained to provide estimates of anode degradation, cathode degradation, or both based on resistance values at different testing points (e.g., different states of charge). Such a model may be trained by test data obtained from a set of test batteries used to evaluate anode degradation, cathode degradation, or a combination of both.

As another example, command module 230 may use resistance or capacitive values of one or more battery models at different states of charge and different discharge/charge current levels to determine a capability for fast vehicle charging. In such an embodiment, command module 230 may receive a prediction model 260 trained to provide estimates of capability for fast vehicle charging based on resistance or capacitive values at different testing points (e.g., different states of charge and different discharge/charge current levels). Such a model may be trained by test data obtained from a set of test batteries used to evaluate capability for fast vehicle charging. As such, changes in resistance or capacitive values of battery models due to different states of charge, different discharge/charge current levels, or both may be used to determine a capability for fast vehicle charging, such as an estimate of remaining possible fast charges, restrictions on fast charging (e.g., not to exceed a voltage or amperage; fast charging not possible), and so on.

In some embodiments, command module 230 may adjust testing points between vehicle charges. For example, vehicle 100 during a trip may charge from 5% to 35% at a first charger, 19% to 65% at a second charger, and then 42% to full capacity at a third charger. In a situation where it is desired to achieve battery tests at every 10% of capacity, command module 230 may omit performing battery tests at 20% and 30% of capacity at the second charger as it has obtained those tests at the first charger and also omit performing battery tests at 50% and 60% of capacity at the third charger as it has obtained those tests at the second charger.

In some embodiments, command module 230 may adjust testing points based on battery history, driver profile, number of fast charges performed, or other factors. For example, as the number of fast charges increase above one or more pre-determined thresholds, command module 230 may adjust testing points to focus on higher states of charge to evaluate battery degradation due to fast charging. As another example, driver behavior may indicate to command module 230 when selecting testing points would be optimal (e.g., due to different patterns in charging behaviors between drivers).

In some embodiments, command module 230 may use resistance or capacitive values of one or more battery models at different states of charge and different discharge/charge current levels to determine a composite battery score. In such an embodiment, command module 230 may receive a prediction model 260 trained to provide a composite battery score that allows for comparing batteries on a pre-determined scale (e.g., 0 to 100) based on resistance or capacitive values at different testing points (e.g., different states of charge and different discharge/charge current levels). Such a model may be trained by test data obtained from a set of test batteries used to determine composite battery scores. Accordingly changes in resistance or capacitive values of battery models due to different states of charge, different discharge/charge current levels, or both may be used to determine a composite battery score.

In some embodiments, vehicle 100 may also include the ability to securely transmit battery health measurements or analysis (e.g., the composite battery score) to a desired service, such as a vehicle diagnostic station or a third-party website hosting vehicle history information.

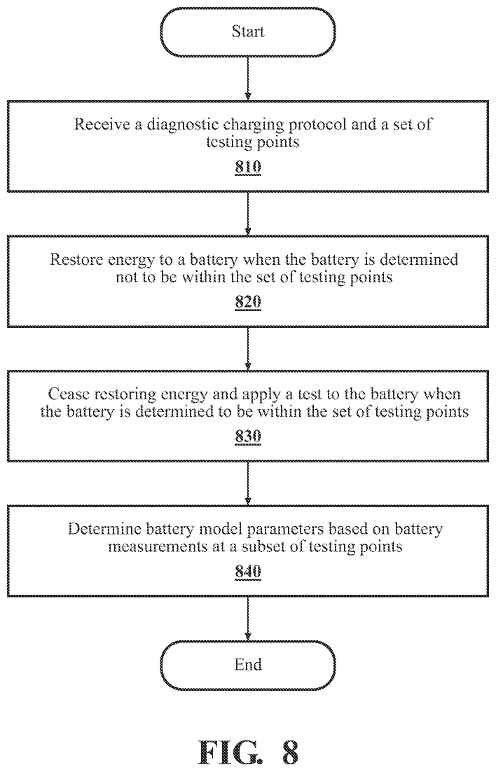

FIG. 8 illustrates a flowchart of a method 800 that is associated with using diagnostic charging strategies. Method 800 will be discussed from the perspective of the battery diagnostic system 170 of FIGS. 1 and 2. While method 800 is discussed in combination with the battery diagnostic system 170, it should be appreciated that the method 800 is not limited to being implemented within battery diagnostic system 170 but is instead one example of a system that may implement method 800.

At step 810, command module 230 may receive a diagnostic charging protocol and a set of testing points. For example, a diagnostic charging protocol may instruct charging to be paused at each testing point and a battery test to be performed once the battery reaches equilibrium. In some embodiments, the set of testing points may be pre-determined, while in other embodiments the testing points may be adjusted or altered. In some embodiments, the adjustment or alteration of the testing points may be performed by the battery diagnostic charging protocol.

At step 820, command module 230 may restore energy to a battery when the battery is determined not to be within the set of testing points. For example, when the battery is not a testing point, it may be charged the same as a battery not undergoing testing.

At step 830, command module 230 may cease restoring energy and apply a test to the battery when the battery is determined to be within the set of testing points. For example, if the battery is at a testing point, charging may be paused to allow the battery to reach equilibrium, after which a battery test, such as an HPPC test, is performed. After the battery test is complete, charging may once again resume.

At step 840, command module 230 may determine battery model parameters based on battery measurements at a subset of testing points. For example, after obtaining a set of battery measurements at different testing points, command module 230 may use machine learning models to determine battery health, the expected number of fast charging events remaining, a composite battery score, or other metrics. In some embodiments, the subset of testing points may be less than the full set of testing points (e.g., because not all testing points were tested, some testing points were invalid), while in other embodiments the subset of testing points may equal the full set of testing points (e.g., because all the testing points were encountered, data across tests was amalgamated to obtain data at all testing points).

FIG. 1 will now be discussed in full detail as an example environment within which the system and methods disclosed herein may operate. In some instances, vehicle 100 is configured to switch selectively between various modes, such as an autonomous mode, one or more semi-autonomous operational modes, a manual mode, etc. Such switching may be implemented in a suitable manner, now known, or later developed. “Manual mode” means that all of or a majority of the navigation/maneuvering of the vehicle is performed according to inputs received from a user (e.g., human driver). In one or more arrangements, vehicle 100 may be a conventional vehicle that is configured to operate in only a manual mode.

In one or more embodiments, vehicle 100 is an autonomous vehicle. As used herein, “autonomous vehicle” refers to a vehicle that operates in an autonomous mode. “Autonomous mode” refers to using one or more computing systems to control vehicle 100, such as providing navigation/maneuvering of vehicle 100 along a travel route, with minimal or no input from a human driver. In one or more embodiments, vehicle 100 is either highly automated or completely automated. In one embodiment, vehicle 100 is configured with one or more semi-autonomous operational modes in which one or more computing systems perform a portion of the navigation/maneuvering of the vehicle along a travel route, and a vehicle operator (i.e., driver) provides inputs to the vehicle to perform a portion of the navigation/maneuvering of vehicle 100 along a travel route.

Vehicle 100 may include one or more processors 110. In one or more arrangements, processor(s) 110 may be a main processor of vehicle 100. For instance, processor(s) 110 may be an electronic control unit (ECU). Vehicle 100 may include one or more data stores 115 for storing one or more types of data. Data store(s) 115 may include volatile memory, non-volatile memory, or both. Examples of suitable data store(s) 115 include RAM (Random Access Memory), flash memory, ROM (Read Only Memory), PROM (Programmable Read-Only Memory), EPROM (Erasable Programmable Read-Only Memory), EEPROM (Electrically Erasable Programmable Read-Only Memory), registers, magnetic disks, optical disks, hard drives, or any other suitable storage medium, or any combination thereof. Data store(s) 115 may be a component of processor(s) 110, or data store 115 may be operatively connected to processor(s) 110 for use thereby. The term “operatively connected,” as used throughout this description, may include direct or indirect connections, including connections without direct physical contact.

In one or more arrangements, data store(s) 115 may include map data 116. Map data 116 may include maps of one or more geographic areas. In some instances, map data 116 may include information or data on roads, traffic control devices, road markings, structures, features, landmarks, or any combination thereof in the one or more geographic areas. Map data 116 may be in any suitable form. In some instances, map data 116 may include aerial views of an area. In some instances, map data 116 may include ground views of an area, including 360-degree ground views. Map data 116 may include measurements, dimensions, distances, information, or any combination thereof for one or more items included in map data 116. Map data 116 may also include measurements, dimensions, distances, information, or any combination thereof relative to other items included in map data 116. Map data 116 may include a digital map with information about road geometry. Map data 116 may be high quality, highly detailed, or both.

In one or more arrangements, map data 116 may include one or more terrain maps 117. Terrain map(s) 117 may include information about the ground, terrain, roads, surfaces, other features, or any combination thereof of one or more geographic areas. Terrain map(s) 117 may include elevation data in the one or more geographic areas. Terrain map(s) 117 may be high quality, highly detailed, or both. Terrain map(s) 117 may define one or more ground surfaces, which may include paved roads, unpaved roads, land, and other things that define a ground surface.

In one or more arrangements, map data 116 may include one or more static obstacle maps 118. Static obstacle map(s) 118 may include information about one or more static obstacles located within one or more geographic areas. A “static obstacle” is a physical object whose position does not change or substantially change over a period of time and whose size does not change or substantially change over a period of time. Examples of static obstacles include trees, buildings, curbs, fences, railings, medians, utility poles, statues, monuments, signs, benches, furniture, mailboxes, large rocks, hills. The static obstacles may be objects that extend above ground level. The one or more static obstacles included in static obstacle map(s) 118 may have location data, size data, dimension data, material data, other data, or any combination thereof, associated with it. Static obstacle map(s) 118 may include measurements, dimensions, distances, information, or any combination thereof for one or more static obstacles. Static obstacle map(s) 118 may be high quality, highly detailed, or both. Static obstacle map(s) 118 may be updated to reflect changes within a mapped area.

Data store(s) 115 may include sensor data 119. In this context, “sensor data” means any information about the sensors that vehicle 100 is equipped with, including the capabilities and other information about such sensors. As will be explained below, vehicle 100 may include sensor system 120. Sensor data 119 may relate to one or more sensors of sensor system 120. As an example, in one or more arrangements, sensor data 119 may include information on one or more LIDAR sensors 124 of sensor system 120.

In some instances, at least a portion of map data 116 or sensor data 119 may be located in data stores(s) 115 located onboard vehicle 100. Alternatively, or in addition, at least a portion of map data 116 or sensor data 119 may be located in data stores(s) 115 that are located remotely from vehicle 100.

As noted above, vehicle 100 may include sensor system 120. Sensor system 120 may include one or more sensors. “Sensor” means any device, component, or system that may detect or sense something. The one or more sensors may be configured to sense, detect, or perform both in real-time. As used herein, the term “real-time” means a level of processing responsiveness that a user or system senses as sufficiently immediate for a particular process or determination to be made, or that enables the processor to keep up with some external process.

In arrangements in which sensor system 120 includes a plurality of sensors, the sensors may work independently from each other. Alternatively, two or more of the sensors may work in combination with each other. In such an embodiment, the two or more sensors may form a sensor network. Sensor system 120, the one or more sensors, or both may be operatively connected to processor(s) 110, data store(s) 115, another element of vehicle 100 (including any of the elements shown in FIG. 1), or any combination thereof. Sensor system 120 may acquire data of at least a portion of the external environment of vehicle 100 (e.g., nearby vehicles).

Sensor system 120 may include any suitable type of sensor. Various examples of different types of sensors will be described herein. However, it will be understood that the embodiments are not limited to the particular sensors described. Sensor system 120 may include one or more vehicle sensors 121. Vehicle sensor(s) 121 may detect, determine, sense, or acquire in a combination thereof information about vehicle 100 itself. In one or more arrangements, vehicle sensor(s) 121 may be configured to detect, sense, or acquire in a combination thereof position and orientation changes of vehicle 100, such as, for example, based on inertial acceleration. In one or more arrangements, vehicle sensor(s) 121 may include one or more accelerometers, one or more gyroscopes, an inertial measurement unit (IMU), a dead-reckoning system, a global navigation satellite system (GNSS), a global positioning system (GPS), a navigation system 147, other suitable sensors, or any combination thereof. Vehicle sensor(s) 121 may be configured to detect, sense, or acquire in a combination thereof one or more characteristics of vehicle 100. In one or more arrangements, vehicle sensor(s) 121 may include a speedometer to determine a current speed of vehicle 100.

Alternatively, or in addition, sensor system 120 may include one or more environment sensors 122 configured to acquire, sense, or acquire in a combination thereof driving environment data. “Driving environment data” includes data or information about the external environment in which an autonomous vehicle is located or one or more portions thereof. For example, environment sensor(s) 122 may be configured to detect, quantify, sense, or acquire in any combination thereof obstacles in at least a portion of the external environment of vehicle 100, information/data about such obstacles, or a combination thereof. Such obstacles may be comprised of stationary objects, dynamic objects, or a combination thereof. Environment sensor(s) 122 may be configured to detect, measure, quantify, sense, or acquire in any combination thereof other things in the external environment of vehicle 100, such as, for example, lane markers, signs, traffic lights, traffic signs, lane lines, crosswalks, curbs proximate to vehicle 100, off-road objects, etc.

Various examples of sensors of sensor system 120 will be described herein. The example sensors may be part of the one or more environment sensor(s) 122, the one or more vehicle sensors 121, or both. However, it will be understood that the embodiments are not limited to the particular sensors described.

As an example, in one or more arrangements, sensor system 120 may include one or more radar sensors 123, one or more LIDAR sensors 124, one or more sonar sensors 125, one or more cameras 126, or any combination thereof. In one or more arrangements, camera(s) 126 may be high dynamic range (HDR) cameras or infrared (IR) cameras.

Vehicle 100 may include an input system 130. An “input system” includes any device, component, system, element or arrangement or groups thereof that enable information/data to be entered into a machine. Input system 130 may receive an input from a vehicle passenger (e.g., a driver or a passenger). Vehicle 100 may include an output system 135. An “output system” includes any device, component, or arrangement or groups thereof that enable information/data to be presented to a vehicle passenger (e.g., a person, a vehicle passenger, etc.).

Vehicle 100 may include one or more vehicle systems 140. Various examples of vehicle system(s) 140 are shown in FIG. 1. However, vehicle 100 may include more, fewer, or different vehicle systems. It should be appreciated that although particular vehicle systems are separately defined, each or any of the systems or portions thereof may be otherwise combined or segregated via hardware, software, or a combination thereof within vehicle 100. Vehicle 100 may include a propulsion system 141, a braking system 142, a steering system 143, throttle system 144, a transmission system 145, a signaling system 146, a navigation system 147, other systems, or any combination thereof. Each of these systems may include one or more devices, components, or combinations thereof, now known or later developed.

Navigation system 147 may include one or more devices, applications, or combinations thereof, now known or later developed, configured to determine the geographic location of the vehicle 100, to determine a travel route for vehicle 100, or to determine both. Navigation system 147 may include one or more mapping applications to determine a travel route for vehicle 100. Navigation system 147 may include a global positioning system, a local positioning system, a geolocation system, or any combination thereof.

Processor(s) 110, battery diagnostic system 170, automated driving module(s) 160, or any combination thereof may be operatively connected to communicate with various aspects of vehicle system(s) 140 or individual components thereof. For example, returning to FIG. 1, processor(s) 110, automated driving module(s) 160, or a combination thereof may be in communication to send or receive information from various aspects of vehicle system(s) 140 to control the movement, speed, maneuvering, heading, direction, etc. of vehicle 100. Processor(s) 110, battery diagnostic system 170, automated driving module(s) 160, or any combination thereof may control some or all of these vehicle system(s) 140 and, thus, may be partially or fully autonomous.

Processor(s) 110, battery diagnostic system 170, automated driving module(s) 160, or any combination thereof may be operable to control at least one of the navigation or maneuvering of vehicle 100 by controlling one or more of vehicle systems 140 or components thereof. For instance, when operating in an autonomous mode, processor(s) 110, battery diagnostic system 170, automated driving module(s) 160, or any combination thereof may control the direction, speed, or both of vehicle 100. Processor(s) 110, battery diagnostic system 170, automated driving module(s) 160, or any combination thereof may cause vehicle 100 to accelerate (e.g., by increasing the supply of fuel provided to the engine), decelerate (e.g., by decreasing the supply of fuel to the engine, by applying brakes), change direction (e.g., by turning the front two wheels), or perform any combination thereof. As used herein, “cause” or “causing” means to make, force, compel, direct, command, instruct, enable, or in any combination thereof an event or action to occur or at least be in a state where such event or action may occur, either in a direct or indirect manner.

Vehicle 100 may include one or more actuators 150. Actuator(s) 150 may be any element or combination of elements operable to modify, adjust, alter, or in any combination thereof one or more of vehicle systems 140 or components thereof to responsive to receiving signals or other inputs from processor(s) 110, automated driving module(s) 160, or a combination thereof. Any suitable actuator may be used. For instance, actuator(s) 150 may include motors, pneumatic actuators, hydraulic pistons, relays, solenoids, and piezoelectric actuators, just to name a few possibilities.

Vehicle 100 may include one or more modules, at least some of which are described herein. The modules may be implemented as computer-readable program code that, when executed by processor(s) 110, implement one or more of the various processes described herein. One or more of the modules may be a component of processor(s) 110, or one or more of the modules may be executed on or distributed among other processing systems to which processor(s) 110 is operatively connected. The modules may include instructions (e.g., program logic) executable by processor(s) 110. Alternatively, or in addition, data store(s) 115 may contain such instructions.

In one or more arrangements, one or more of the modules described herein may include artificial or computational intelligence elements, e.g., neural network, fuzzy logic, or other machine learning algorithms. Further, in one or more arrangements, one or more of the modules may be distributed among a plurality of the modules described herein. In one or more arrangements, two or more of the modules described herein may be combined into a single module.

Vehicle 100 may include one or more autonomous driving modules 160. Automated driving module(s) 160 may be configured to receive data from sensor system 120 or any other type of system capable of capturing information relating to vehicle 100, the external environment of the vehicle 100, or a combination thereof. In one or more arrangements, automated driving module(s) 160 may use such data to generate one or more driving scene models. Automated driving module(s) 160 may determine position and velocity of vehicle 100. Automated driving module(s) 160 may determine the location of obstacles, obstacles, or other environmental features including traffic signs, trees, shrubs, neighboring vehicles, pedestrians, etc.

Automated driving module(s) 160 may be configured to receive, determine, or in a combination thereof location information for obstacles within the external environment of vehicle 100, which may be used by processor(s) 110, one or more of the modules described herein, or any combination thereof to estimate: a position or orientation of vehicle 100; a vehicle position or orientation in global coordinates based on signals from a plurality of satellites or other geolocation systems; or any other data/signals that could be used to determine a position or orientation of vehicle 100 with respect to its environment for use in either creating a map or determining the position of vehicle 100 in respect to map data.

Automated driving module(s) 160 either independently or in combination with battery diagnostic system 170 may be configured to determine travel path(s), current autonomous driving maneuvers for vehicle 100, future autonomous driving maneuvers, modifications to current autonomous driving maneuvers, etc. Such determinations by automated driving module(s) 160 may be based on data acquired by sensor system 120, driving scene models, data from any other suitable source such as determinations from sensor data 250, or any combination thereof. In general, automated driving module(s) 160 may function to implement different levels of automation, including advanced driving assistance (ADAS) functions, semi-autonomous functions, and fully autonomous functions. “Driving maneuver” means one or more actions that affect the movement of a vehicle. Examples of driving maneuvers include accelerating, decelerating, braking, turning, moving in a lateral direction of vehicle 100, changing travel lanes, merging into a travel lane, and reversing, just to name a few possibilities. Automated driving module(s) 160 may be configured to implement driving maneuvers. Automated driving module(s) 160 may cause, directly or indirectly, such autonomous driving maneuvers to be implemented. As used herein, “cause” or “causing” means to make, command, instruct, enable, or in any combination thereof an event or action to occur or at least be in a state where such event or action may occur, either in a direct or indirect manner. Automated driving module(s) 160 may be configured to execute various vehicle functions, whether individually or in combination, to transmit data to, receive data from, interact with, or to control vehicle 100 or one or more systems thereof (e.g., one or more of vehicle systems 140).

Detailed embodiments are disclosed herein. However, it is to be understood that the disclosed embodiments are intended only as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in FIGS. 1-8, but the embodiments are not limited to the illustrated structure or application.

The flowcharts and block diagrams in the figures illustrate the architecture, functionality, and operation of possible implementations of systems, methods, and computer program products according to various embodiments. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components, or processes described above may be realized in hardware or a combination of hardware and software and may be realized in a centralized fashion in one processing system or in a distributed fashion where different elements are spread across several interconnected processing systems. Any kind of processing system or another apparatus adapted for carrying out the methods described herein is suited. A typical combination of hardware and software may be a processing system with computer-usable program code that, when being loaded and executed, controls the processing system such that it carries out the methods described herein. The systems, components, or processes also may be embedded in a computer-readable storage, such as a computer program product or other data programs storage device, readable by a machine, tangibly embodying a program of instructions executable by the machine to perform methods and processes described herein. These elements also may be embedded in an application product which comprises all the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: a portable computer diskette, a hard disk drive (HDD), a solid-state drive (SSD), a read-only memory (ROM), an erasable programmable read-only memory (EPROM or Flash memory), a portable compact disc read-only memory (CD-ROM), a digital versatile disc (DVD), an optical storage device, a magnetic storage device, or any suitable combination of the foregoing. In the context of this document, a computer-readable storage medium may be any tangible medium that may contain or store a program for use by or in connection with an instruction execution system, apparatus, or device.

Generally, modules as used herein include routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an application-specific integrated circuit (ASIC), a hardware component of a system on a chip (SoC), as a programmable logic array (PLA), or as another suitable hardware component that is embedded with a defined configuration set (e.g., instructions) for performing the disclosed functions.

Program code embodied on a computer-readable medium may be transmitted using any appropriate medium, including but not limited to wireless, wireline, optical fiber, cable, RF, etc., or any suitable combination of the foregoing. Computer program code for carrying out operations for aspects of the present arrangements may be written in any combination of one or more programming languages, including an object-oriented programming language such as Java™, Smalltalk, C++, or the like and conventional procedural programming languages, such as the “C” programming language or similar programming languages. The program code may execute entirely on a user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and “having,” as used herein, are defined as comprising (i.e., open language). The phrase “at least one of . . . and . . . ” as used herein refers to and encompasses any and all possible combinations of one or more of the associated listed items. As an example, the phrase “at least one of A, B, and C” includes A only, B only, C only, or any combination thereof (e.g., AB, AC, BC, or ABC).

Aspects herein may be embodied in other forms without departing from the spirit or essential attributes thereof. Accordingly, reference should be made to the following claims, rather than to the foregoing specification, as indicating the scope hereof.

What is claimed is:

1. A system, comprising:
a processor; and
a memory communicably coupled to the processor and storing machine-readable instructions that, when executed by the processor, cause the processor to:
receive a diagnostic charging protocol and a set of testing points;
restore energy to a battery when the battery is determined not to be within the set of testing points;
cease restoring energy and apply a test to the battery when the battery is determined to be within the set of testing points; and
determine battery model parameters based on battery measurements at a subset of testing points.

2. The system of claim 1, wherein the machine-readable instructions to test the battery uses different discharge/charge levels.

3. The system of claim 1, wherein the machine-readable instructions to test the battery uses hybrid pulse power characterization.

4. The system of claim 1, wherein the machine-readable instructions that, when executed by the processor, further includes causing the processor to:
obtain an estimate of electrode degradation based on a set of battery model parameters.

5. The system of claim 1, wherein the machine-readable instructions that, when executed by the processor, further includes causing the processor to:
obtain an estimate of a capability for fast charging based on a set of battery model parameters.

6. The system of claim 4, wherein the machine-readable instructions that, when executed by the processor, further includes causing the processor to:
display the estimate of electrode degradation.

7. The system of claim 5, wherein the machine-readable instructions that, when executed by the processor, further includes causing the processor to:
restrict fast charging based on if the capability for fast charging satisfies a criteria.

8. A non-transitory computer-readable medium including instructions that when executed by one or more processors cause the one or more processors to:
receive a diagnostic charging protocol and a set of testing points;
restore energy to a battery when the battery is determined not to be within the set of testing points;
cease restoring energy and apply a test to the battery when the battery is determined to be within the set of testing points; and
determine battery model parameters based on battery measurements at a subset of testing points.

9. The non-transitory computer-readable medium of claim 8, wherein the instructions to test the battery uses different discharge/charge levels.

10. The non-transitory computer-readable medium of claim 8, wherein the instructions to test the battery uses hybrid pulse power characterization.

11. The non-transitory computer-readable medium of claim 8, wherein the instructions further include to:
obtain an estimate of electrode degradation based on a set of battery model parameters.

12. The non-transitory computer-readable medium of claim 8, wherein the instructions further include to:
obtain an estimate of a capability for fast charging based on a set of battery model parameters.

13. The non-transitory computer-readable medium of claim 12, wherein the instructions further include to:
restrict fast charging based on if the capability for fast charging satisfies a criteria.

14. A method, comprising:
receiving a diagnostic charging protocol and a set of testing points;
restoring energy to a battery when the battery is determined not to be within the set of testing points;
ceasing restoring energy and apply a test to the battery when the battery is determined to be within the set of testing points; and
determining battery model parameters based on battery measurements at a subset of testing points.

15. The method of claim 14, wherein the test to the battery uses different discharge/charge levels.

16. The method of claim 14, wherein the test to the battery uses hybrid pulse power characterization.

17. The method of claim 14, further comprising:
obtaining an estimate of electrode degradation based on a set of battery model parameters.

18. The method of claim 14, further comprising:
obtaining an estimate of a capability for fast charging based on a set of battery model parameters.

19. The method of claim 17, further comprising:
displaying the estimate of electrode degradation.

20. The method of claim 18, further comprising:
restricting fast charging based on if the capability for fast charging satisfies a criteria.
